(19) United States
(12) Patent Application Publication
(10) Pub. No.: US 2025/0279386 A1
(43) Pub. Date: Sep. 4, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: JUNGHOON KANG, Suwon-si (KR)

(21) Appl. No.: 18/886,851

(22) Filed: Sep. 16, 2024

(30) Foreign Application Priority Data
Feb. 29, 2024 (KR) 10-2024-0030271

(51) Int. Cl. H01L 23/00; H01L 25/065; H01L 25/18; H10B 80/00

(52) U.S. Cl. CPC H01L 24/29; H01L 24/04; H01L 24/05; H01L 24/16; H01L 24/32; H01L 24/73; H01L 24/81; H01L 25/0657; H01L 25/18; H01L 2224/0401; H01L 2224/05082; H01L 2224/05155; H01L 2224/05644; H01L 2224/16227; H01L 2224/29186; H01L 2224/29347; H01L 2224/29355; H01L 2224/29409; H01L 2224/29411; H01L 2224/29439; H01L 2224/29444; H01L 2224/29447; H01L 2224/29455; H01L 2224/29457; H01L 2224/29464; H01L 2224/29469; H01L 2224/29487; H01L 2224/32225; H01L 2224/73204; H01L 2224/81125; H01L 2225/06513; H01L 2924/1431; H01L 2924/1436; H10B 80/00

(57) ABSTRACT

A semiconductor package according to an embodiment includes a first semiconductor die, a plurality of bonding pads on the first semiconductor die, a plurality of connection members on the plurality of bonding pads, wherein each connection member of the plurality of connection members is disposed on a corresponding bonding pad of the plurality of bonding pads, a second semiconductor die on the plurality of connection members, and an anisotropic conductive film between the first semiconductor die and the second semiconductor die, and between the plurality of bonding pads and the plurality of connection members, including an insulating film, and conductive particles inside the insulating film, wherein the conductive particles are positioned between each of the plurality of connection members and the corresponding bonding pad of the plurality of bonding pads.

### CROSS-REFERENCE TO RELATED APPLICATION

This application claims priority to and the benefit of Korean Patent Application No. 10-2024-0030271 filed in the Korean Intellectual Property Office on Feb. 29, 2024, the entire contents of which are incorporated herein by reference.

### BACKGROUND OF THE INVENTION

### (a) Field of the Invention

The present disclosure relates to a semiconductor package and a method for manufacturing the same.

### (b) Description of the Related Art

The semiconductor industry is pursuing down-sizing, lightening, and thinning the semiconductor packages mounted in electronic devices, while simultaneously pursuing higher speed, multifunction, and large capacity, in response to the demand for down-sizing and lightening of electronic devices. Therefore, the need for packaging technology capable of storing more data and transmitting data at a higher speed is increasing, and a stacked semiconductor device formed by stacking multiple individual semiconductor dies, such as three-dimensional integrated circuit (3DIC), is being developed as such packaging technology.

Stacked semiconductor devices are manufactured by bonding same or different types of semiconductor chips with connection members. In the case of a stacked semiconductor device in which the pitch of the connection members is designed to be about 21 μm to about 100 μm, bumps and a nonconductive film (NCF) are used to bond the semiconductor dies. In the case of a stacked semiconductor device in which the pitch of the connection members is designed to be about 4 μm to about 20 μm, a hybrid bonding process is performed to bond the semiconductor dies.

The hybrid bonding process may be applied to a stacking process to manufacture a stacked semiconductor device that cannot use bumps and nonconductive film (NCF) and requires ultra-fine pitch. However, the hybrid bonding process requires high-precision equipment to perform hybrid bonding, and there is an issue in that the bonding surface of each semiconductor die must be managed to have a surface roughness of about 10 Å or less to prevent connection defects.

### SUMMARY OF THE INVENTION

In a semiconductor package including a first semiconductor die, a plurality of bonding pads on the first semiconductor die, connection members on the bonding pads, and a second semiconductor die on the connection members, an anisotropic conductive film (ACF) may be disposed between the first semiconductor die and the second semiconductor die.

The anisotropic conductive film includes conductive particles locally positioned between each of the connection members and a corresponding bonding pad of the bonding pads, and around each of the connection members and a corresponding bonding pad of the bonding pads. The conductive particles may electrically connect each of the connection members to the corresponding bonding pad of the bonding pads.

A semiconductor package according to an embodiment, includes a first semiconductor die, a plurality of bonding pads on the first semiconductor die, a plurality of connection members on the plurality of bonding pads, wherein each of the plurality of connection members is disposed on a corresponding bonding pad of the plurality of bonding pads, a second semiconductor die on the plurality of connection members, and an anisotropic conductive film between the first semiconductor die and the second semiconductor die, and between the plurality of bonding pads and the plurality of connection members, including an insulating film, and conductive particles inside the insulating film, wherein the conductive particles are positioned between each of the plurality of connection members and the corresponding bonding pad of the plurality of bonding pads.

A semiconductor package according to an embodiment includes a first semiconductor die, a second semiconductor die on the first semiconductor die, and an interconnection structure between the first semiconductor die and the second semiconductor die, wherein the interconnection structure includes a plurality of bonding pads on the first semiconductor die, a plurality of connection members under the second semiconductor die, wherein each connection member of the plurality of connection members is disposed on a corresponding bonding pad of the plurality of bonding pads, and an anisotropic conductive film surrounding the plurality of bonding pads and the plurality of connection members, wherein the anisotropic conductive film comprises first regions and a second region other than the first regions, wherein the first regions and the second region are defined by dividing a plane of the anisotropic conductive film, each first region of the first regions is defined around the corresponding bonding pad of the plurality of bonding pads, around a corresponding connection member of the plurality of connection members, and between the corresponding bonding pad of the plurality of bonding pads and the corresponding connection member of the plurality of connection members, the anisotropic conductive film includes an insulating film and conductive particles inside the insulating film, and the conductive particles are positioned only in the first regions.

A method for manufacturing a semiconductor package includes forming an anisotropic conductive film by inserting conductive particles into each first region of first regions of an insulating film, wherein the insulating film comprises first regions and a second region other than the first regions, and the first regions and the second region are defined by dividing a plane of the insulating film, attaching the anisotropic conductive film on an upper semiconductor die on which a plurality of connection members are disposed, wherein each first region of the first regions covers a corresponding connection member of the plurality of connection members, aligning the upper semiconductor die on which the plurality of connection members are disposed on a lower semiconductor die on which a plurality of bonding pads are disposed, and inserting each of the plurality of bonding pads into each first region of the first regions, and bonding each of the plurality of bonding pads to a corresponding connection member of the plurality of connection members, wherein the conductive particles are positioned between each of the plurality of bonding pads and the corresponding connection member of the plurality of connection members.

The anisotropic conductive film (ACF) may be used as an interconnection structure that connects the first semiconductor die and the second semiconductor die of a stacked semiconductor device requiring ultra-fine pitch, and includes locally positioned conductive particles.

As a result, high-precision equipment required in the hybrid bonding process may not be required, and the surface roughness of the bonding surface of the semiconductor die, which is managed to prevent connection defects that may occur in the hybrid bonding process, may not need to be managed.

The conductive particles in the anisotropic conductive film (ACF) are locally positioned between each of the connection members and a corresponding bonding pad of the bonding pads, and around each of the connection members and a corresponding bonding pad of the bonding pads. Therefore, a reliable electrical connection may be made between the connection members and the bonding pads, even when increasing the content of conductive particles within the anisotropic conductive film (ACF) or minimizing the size of the conductive particles, connection defects that short-circuit the circuit do not occur.

### BRIEF DESCRIPTION OF THE DRAWINGS

FIG. 1 is a cross-sectional view illustrating a semiconductor stacking structure according to an embodiment.

FIG. 2 is an enlarged cross-sectional view of region A of the semiconductor stacking structure of FIG. 1.

FIG. 3 is a cross-sectional view illustrating a semiconductor package according to an embodiment.

FIG. 4 is a cross-sectional view illustrating a semiconductor package according to another embodiment.

FIGS. 5 to 12 are cross-sectional views illustrating a method of manufacturing an anisotropic conductive film (ACF) according to an embodiment.

FIGS. 13 to 16 are cross-sectional views illustrating a method of manufacturing the semiconductor stacking structure according to an embodiment of FIG. 1.

### DETAILED DESCRIPTION OF THE EMBODIMENTS

Hereinafter, the present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Size and thickness of each constituent element in the drawings may be arbitrarily illustrated for better understanding and ease of description, the following embodiments are not limited thereto.

Throughout the specification, the term “connected” does not mean only that two or more constituent components are directly connected, but may also mean that two or more constituent components are indirectly connected through another constituent component. Throughout the specification, when a component is described as “comprising” “including” (or variations thereof) a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element such as a layer, film, region, or substrate is referred to as being “on” another element, it can be directly on the other element or intervening elements may also be present. In contrast, when an element is referred to as being “directly on” another element, the elements are in contact with each other and there are no intervening elements present at the point of contact. Further, when an element is referred to as being “above” or “on” a reference element, it can be positioned above or below the reference element, and it is not necessarily referred to as being positioned “above” or “on” in a direction opposite to gravity.

Further, throughout the specification, the phrase “in a plan view” refers to viewing a target portion from the top, and the phrase “in a cross-sectional view” or “on a cross-section” means viewing a cross-section formed by vertically cutting a target portion from the side.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Hereinafter, a semiconductor stacking structure 100, semiconductor packages 10 and 20, and a method of manufacturing the semiconductor stacking structure 100 according to an embodiment will be described with reference to the drawings.

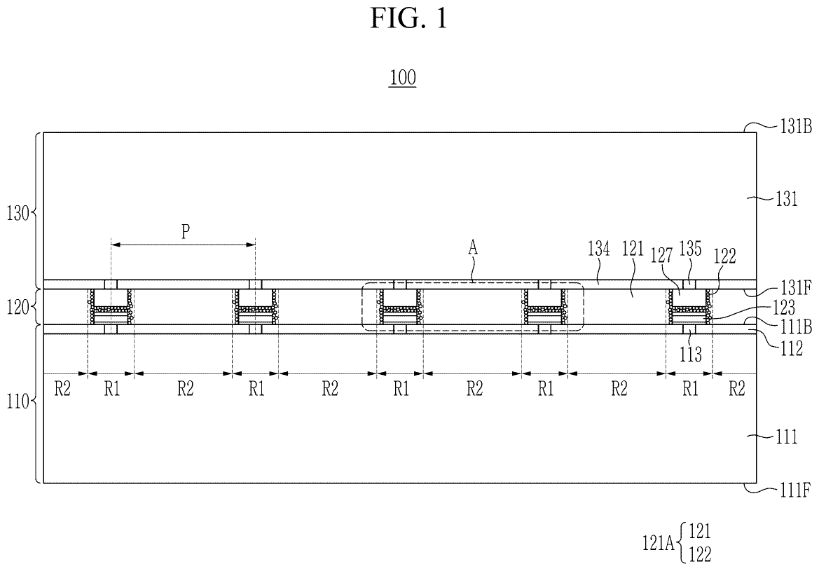

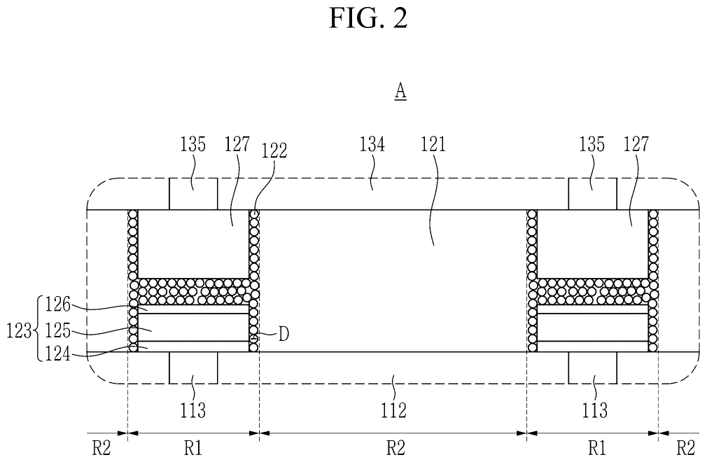

FIG. 1 is a cross-sectional view illustrating the semiconductor stacking structure 100 according to an embodiment. FIG. 2 is an enlarged cross-sectional view of region A of the semiconductor stacking structure 100 of FIG. 1.

Referring to FIG. 1, the semiconductor stacking structure 100 includes a first semiconductor die (lower semiconductor die) 110, an interconnection structure 120, and a second semiconductor die (upper semiconductor die) 130. In an embodiment, the semiconductor stacking structure 100 may be a stacking structure of semiconductor dies used in high bandwidth memory (HBM) or 3DIC. In an embodiment, the semiconductor stacking structure 100 may be manufactured based on fan out wafer level package (FOWLP) or fan out panel level package (FOPLP) technology.

In an embodiment, a first semiconductor die 110 and a second semiconductor die 130 may be the same type (e.g., identical). In an embodiment, the first semiconductor die 110 and the second semiconductor die 130 may be different type.

The first semiconductor die 110 includes a first die base 111, a first dielectric layer 112, and through substrate vias 113. The first die base 111 includes a substrate having active regions formed therein, and a wiring layer on the active regions. The first die base 111 has a front side 111F corresponding to the side of the substrate in which the active regions are formed (and corresponding to the side on which the wiring layer is formed). The front side of the die base 111 corresponds to the front side of the first semiconductor die 110. The first die base 111 has a back side 111B opposite to the front side 111F, the back side 111B corresponding to the back side of the first semiconductor die 110). The wiring layer may include several metal layers separated by interlayer dielectric layers, where patterns of the metal layers are interconnected to form wiring. The active regions may be used to form transistors that are interconnected by wiring of the wiring layer to form logic circuits (e.g., NAND, NOR, inverters, etc.). The logic circuits may be interconnected by the wiring of the wiring layer to form an integrated circuit of the first semiconductor die 110, such as a memory integrated circuit or a logic device integrated circuit. The wiring layer includes signal wiring that transmits signals between the first semiconductor die 110 and external devices (such as the second semiconductor die 130) and power wiring that transmits power to the first semiconductor die 110. The backside 111B of the first die base 111 may be the backside of the first semiconductor die 110 and may not have any active regions formed therein, nor any transistors formed with the backside 111B of the substrate of the first semiconductor die 110.

The term “substrate” may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.).

The first dielectric layer 112 is formed on the back side of the substrate. In an embodiment, the first dielectric layer 112 may include at least one of a silicon oxide layer and a silicon nitride layer. The first dielectric layer may be a passivation layer and forms an external surface of the semiconductor die 110.

The through substrate vias (TSV) 113 (which may be through silicon vias) penetrate the first dielectric layer 112 and contact the bonding pads 123. The through substrate vias (TSV) 113 extend through the substrate and wiring layer of the first die base 111 and may extend fully through the first semiconductor chip 110 to the bonding pads 123. Each of the through substrate vias (TSV) 113 is electrically connected to a corresponding bonding pad of the bonding pads 123. In an embodiment, the through substrate vias (TSV) 113 may include at least one of tungsten, aluminum, copper, and alloys thereof. In an embodiment, an insulating layer (not shown) may be formed around a side surface of each of the through substrate vias (TSV) 113. In an embodiment, an insulating layer (not shown) may be formed between the through substrate vias (TSV) 113 and the substrate, and between the through substrate vias (TSV) 113 and the first dielectric layer 112. In an embodiment, the insulating layer (not shown) may include at least one of an oxide layer, a nitride layer, a carbonization layer, and a polymer. In an embodiment, the insulating layer (not shown) may be an ozone/tetra-ethyl ortho-silicate (O3/TEOS)-based high aspect ratio process (HARP) oxide layer formed by a sub-atmospheric chemical vapor deposition (CVD) process.

The interconnection structure 120 is disposed between the first semiconductor die 110 and the second semiconductor die 130. The interconnection structure 120 is disposed between the back side 111B of the first semiconductor die 110 and the front side 131F of the second semiconductor die 130. The interconnection structure 120 includes an anisotropic conductive film (ACF) 121A, bonding pads 123, and connection members 127.

The anisotropic conductive film (ACF) 121A is disposed between the first semiconductor die 110 and the second semiconductor die 130, and between the bonding pads 123 and the connection members 127. The anisotropic conductive film (ACF) 121A surrounds the bonding pads 123 and the connection members 127. The anisotropic conductive film (ACF) 121A includes an insulating film 121 and conductive particles 122. The insulating film 121 is adhered to the first semiconductor die 110 and the second semiconductor die 130 to fix the first semiconductor die 110 to the second semiconductor die 130, and has the function of insulating and protecting the bonding pads 123 and the connection members 127. In an embodiment, the insulating film 121 may include a polymer film. In an embodiment, the insulating film 121 may include thermosetting resin. In an embodiment, the insulating film 121 may include acrylic resin or epoxy resin. In an embodiment, the insulating film 121 may be a non-conducting film (NCF).

The anisotropic conductive film (ACF) 121A includes first regions R1 and a second region R2. The second region R2 may be the portion of the anisotropic conductive film (ACF) 121A that is not the first regions R1. Although not shown in the cross sectional views of the figures, the second region R2 may be continuous while the first regions R1 may be separate from each other, being separated by the second region R2. With respect to a top down view, the first regions may be islands within the second region R2. Each first region R1 may be a region surrounding a corresponding one of the bonding pads 123, a corresponding one of the connection members 127, and the region therebetween. In an embodiment, with respect to a plan view, each of the first regions R1 may have a circular, oval, polygonal, or conformal shape around each of the connection members 127.

The conductive particles 122 are included inside the insulating film 121. Referring to FIG. 2, the conductive particles 122 are positioned within each first region of the first regions R1. The conductive particles 122 are not positioned in the second region R2. The conductive particles 122 are positioned between each connection member 127 and the bonding pad 123 adjacent to this connection member 127. The conductive particles 122 may electrically connect each of the connection members 127 to a corresponding bonding pad among the bonding pads 123. With respect to plan view, the conductive particles 122 are positioned to surround each of the bonding pads 123 and to surround each of the connection members 127.

Some of the conductive particles 122 contact the side surface of a bonding pad 123. Some of the conductive particles 122 contact the side surface of a connection member 127.

The conductive particles 122 are positioned within a predetermined distance in the horizontal direction from the side surface of a corresponding bonding pad 123. The conductive particles 122 are positioned within a predetermined distance in the horizontal direction from the side surface of a corresponding connection member 127.

In an embodiment, each of the conductive particles 122 may be metal particles coated with a conductive metal layer, or polymer particles coated with a conductive metal layer. In an embodiment, the metal particles may be formed of a metal material with high hardness. In an embodiment, the metal particle may include nickel, solder, or copper. In an embodiment, the polymer particles may be polymer balls. In an embodiment, the conductive metal layer may be formed by performing an electrolytic plating process, an electroless plating process, or a chemical vapor deposition (CVD) process on the metal particles or the polymer particles. In an embodiment, the conductive metal layer may include at least one of nickel, gold, silver, copper, platinum, palladium, cobalt, tin, indium, and indium tin oxide (ITO). In an embodiment, each of the conductive particles 122 may have a spherical or non-spherical shape. In an embodiment, the conductive particles 122 may have a diameter D in the range of 10 nanometers (nm) to 20 micrometers (μm).

The bonding pads 123 are disposed on the first dielectric layer 112 of the first semiconductor die 110. Each of the bonding pads 123 is electrically connected to a corresponding through silicon via (TSV) 113. In an embodiment, the horizontal pitch P between neighboring bonding pads 123 may be in the range of 4 μm to 100 μm. Referring to FIG. 2, the bonding pad 123 includes a first pad layer 124, a second pad layer 125, and a third pad layer 126.

The first pad layer 124 is disposed on and contacts the through silicon via (TSV) 113 and is electrically connected to the through silicon via (TSV) 113. The first pad layer 124 includes a barrier layer and a seed metal layer. The barrier layer is made of a material that is difficult to diffuse into the first dielectric layer 112 and prevents the metal component of the seed metal layer from diffusing into the first dielectric layer 112. In an embodiment, the barrier layer may include titanium, tantalum, a titanium alloy, a tantalum alloy, a titanium nitride layer, or a tantalum nitride layer. In an embodiment, the barrier layer may be formed by performing a sputtering process. In an embodiment, the seed metal layer may include copper. In an embodiment, the seed metal layer may be formed by performing an electroless plating process. In an embodiment, a cleaning process or a metal catalyst activation pretreatment process may be performed prior to electroless plating. In an embodiment, the seed metal layer may be formed by performing a sputtering process.

A second pad layer (nickel layer) 125 is disposed on the first pad layer 124. The second pad layer 125 serves to reduce the resistance of the bonding pad 123. In an embodiment, the second pad layer 125 may include nickel. In an embodiment, the second pad layer 125 may be formed by performing an electroplating process. In an embodiment, the second pad layer 125 may have a vertical dimension, e.g., a thickness, greater than the vertical dimension, e.g., the thickness, of the first pad layer 124 and the vertical dimension, e.g., the thickness, of the third pad layer 126.

A third pad layer (gold layer) 126 is disposed on the second pad layer 125. The third pad layer 126 serves to improve adhesion to the conductive particles 122. In an embodiment, the third pad layer 126 may include gold. In an embodiment, the third pad layer 126 may be formed by performing an electroplating process. In an embodiment, the third pad layer 126 may have a vertical dimension, e.g., a thickness, that is thinner than the vertical dimension, e.g., the thickness, of the second pad layer 125.

According to the present disclosure, the bonding pad 123 including the first pad layer 124, the second pad layer 125, and the third pad layer 126 is described, but is not limited thereto, and the bonding pad 123 including fewer or more pad layers may be included within the present disclosure as needed.

The connection members 127 are disposed below the second dielectric layer 134 of the second semiconductor die 130. Each of the connection members 127 is disposed on a corresponding one of the bonding pads 123. Each of the connection members 127 electrically connects a corresponding one of the contact vias 135 of the second semiconductor die 130 to the corresponding one of bonding pads 123 of the first semiconductor die 110 via the conductive particles 122.

In an embodiment, the horizontal pitch P between neighboring connection members among the connection members 127 may be 4 μm to about μm. In an embodiment, the connection members 127 may include micro bumps (e.g., conductive balls or pillars). In an embodiment, the connection members 127 may include at least one of copper, aluminum, tungsten, nickel, gold, silver, tin, titanium, and alloys thereof.

The second semiconductor die 130 includes a second die base 131, a second dielectric layer 134, and contact vias 135. The second die base 131 includes a substrate, active regions formed in the substrate, and a wiring layer on the active regions. The second die base 131 has the front side 131F corresponding to the side of the substrate in which the active regions are formed (and corresponding to the side on which the wiring layer is formed). The front side of the second die base 131 corresponds to the front die of the second semiconductor die 130. The second die base has back side 131B opposite to the front side 131F, the back side 131 corresponding to the back side of the second semiconductor die 130. The wiring layer and active regions of the second semiconductor die may form transistors, logic circuits and an integrated circuit (e.g. an integrated circuit of a memory device or an integrated circuit of a logic device) as described with respect to the first semiconductor die 110 (i.e., with respect to the front side of the second semiconductor die 130). Similarly, the backside of the second semiconductor die 130 may not be provided with transistors. The wiring layer includes signal wiring that transmits signals between the second semiconductor die 130 and external devices and power wiring that transmits power to the second semiconductor die 130.

The second dielectric layer 134 is positioned on the front side 131F of the substrate and is formed to cover the wiring layer. In an embodiment, the second dielectric layer 134 may include a silicon nitride layer. The contact vias 135 penetrate the second dielectric layer 134 and contact the connection members 127. Each of the contact vias 135 is disposed between a bonding pad (not shown) and each of the connection members 127. Each of the contact vias 135 is electrically connected to each of the connection members 127. In an embodiment, the contact vias 135 may include at least one of copper, aluminum, tungsten, nickel, gold, silver, tin, titanium, and alloys thereof.

According to the present disclosure, the conductive particles 122 may be disposed only in first regions R1 of the anisotropic conductive film (ACF) 121A which are regions surrounding the bonding pads 123, surrounding each of the connection members 127, and between each of the bonding pads 123 and each of the connection members 127.

By disposing the conductive particles 122 only in the first regions R1 as described above, the content of the conductive particles 122 per unit area of the insulating film 121 within the first regions R1 increases significantly, thereby improving electrical characteristics between the bonding pads 123 and the connection members 127. In addition, the size of the conductive particles 122 in the first regions R1 may be reduced to significantly increase the contact area between the conductive particles 122, thereby improving the electrical characteristics between the bonding pads 123 and the connection members 127. The content of conductive particles 122 in the second region R2 is 0 or substantially 0.

Contrary to the present disclosure, if the content of conductive particles 122 within the insulating film 121 is increased, or the size of the conductive particles 122 is decreased, to improve electrical characteristics, without limiting the regions where the conductive particles 122 are disposed, the conductive particles 122 may become spread out within the insulating film 121, resulting in poor contact between the bonding pads 123 and the connection members 127.

In this way, by disposing the conductive particles 122 only in the first regions R1 of the anisotropic conductive film (ACF) 121A for the electrical connection between the bonding pads 123 and the connection members 127, it is possible to apply the bonding process of the anisotropic conductive film (ACF) 121A according to the present disclosure, without applying a hybrid bonding process to the semiconductor stacking structure 100 where the pitch of the connection members is designed to be ultra-fine pitch (for example, in a range of 4 μm to 20 μm). Accordingly, high-precision equipment required in the hybrid bonding process may not be required, and the surface roughness of the bonding surface of the semiconductor die, which is managed to prevent connection defects that may occur in the hybrid bonding process, does not have to be managed.

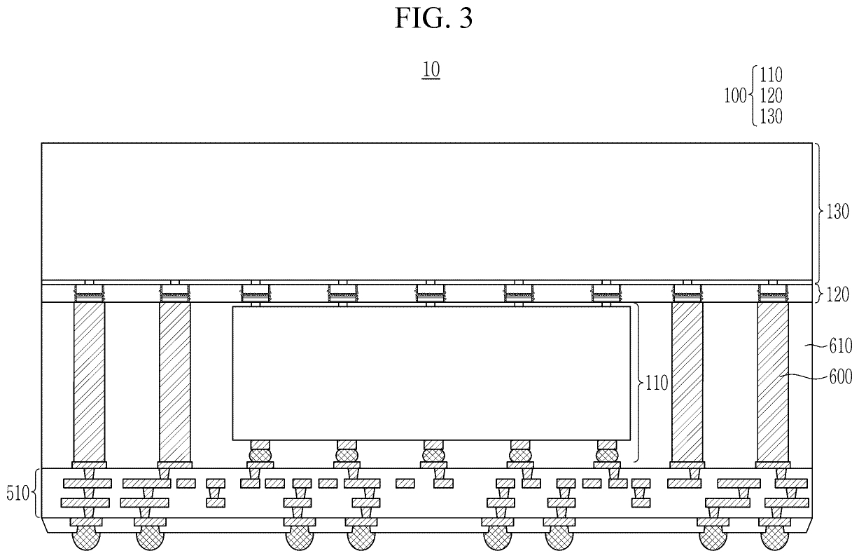

FIG. 3 is a cross-sectional view illustrating a semiconductor package 10 according to an embodiment.

Referring to FIG. 3, the semiconductor package 10 includes a redistribution structure 510, the semiconductor stacking structure 100 on the redistribution structure 510, conductive posts 600 on the redistribution structure 510, and a molding material 610 that covers the first semiconductor die 110 on the redistribution structure 510. The semiconductor stacking structure 100 may be that described with respect to FIGS. 1 and 2 and includes the first semiconductor die 110, the interconnection structure 120, and the second semiconductor die 130. In an embodiment, the semiconductor package 10 may include a system on chip (SoC). In an embodiment, the semiconductor package 10 may include a three-dimensional integrated circuit (3DIC). In an embodiment, the first semiconductor die 110 may be the lower die of a 3D integrated circuit. In an embodiment, the second semiconductor die 130 may be the upper die of a 3D integrated circuit. The footprint of the first semiconductor die 110 is included within the footprint of the second semiconductor die 130. The second semiconductor die 130 has a larger horizontal area (i.e., with respect to a plan view) than the first semiconductor die 110.

The first semiconductor die 110 is a different die from a second semiconductor die 130. The semiconductor package 10 has a structure in which different types of dies are stacked. In an embodiment, the first semiconductor die 110 may include a central processing unit (CPU) or a graphic processing unit (GPU). In an embodiment, the second semiconductor die 130 may include at least one of a memory, a communication chip, a controller, and a sensor.

In the semiconductor package 10 manufactured based on fan out wafer level package (FOWLP) or fan out panel level package (FOPLP) technology, the interconnection structure 120 connects the second semiconductor die 130 to the first semiconductor die 110, and connects the second semiconductor die 130 to the conductive posts 600. In this case, the pitch between neighboring bonding pads among the bonding pads 123 connected to the first semiconductor die 110 and the pitch between neighboring connection members among the connection members 127 connected thereto are smaller than the pitch between neighboring bonding pads among the bonding pads 123 connected to the conductive posts 600 and the pitch between neighboring connection members among the connection members 127 connected thereto.

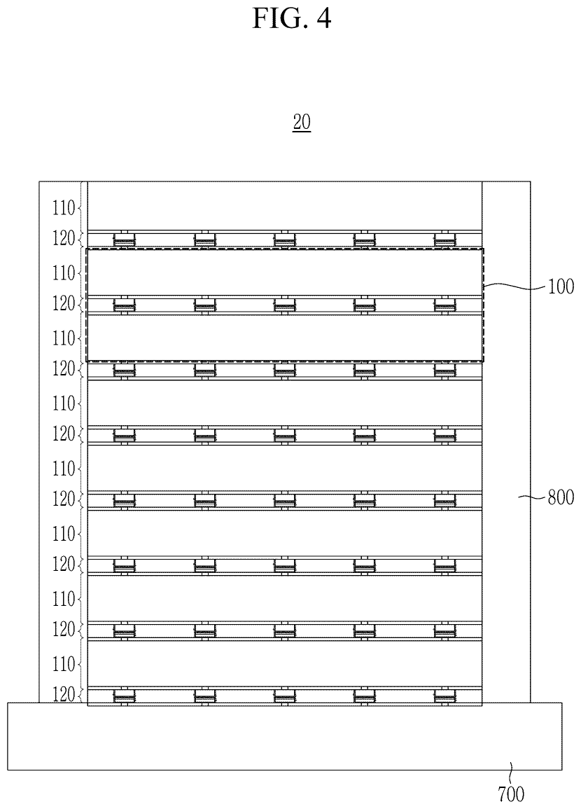

FIG. 4 is a cross-sectional view illustrating a semiconductor package 20 according to another embodiment.

Referring to FIG. 4, the semiconductor package 20 includes a plurality of semiconductor stacking structures 100. The semiconductor package 20 has a structure in which first semiconductor dies 110 are alternately stacked. Each adjacent pair of first semiconductor dies 110 and the interconnection structure 120 therebetween may correspond to the semiconductor stacking structures 100 described herein with respect to FIGS. 1 and 2. The semiconductor package 20 has a structure in which dies of the same type are stacked. In an embodiment, the semiconductor package 20 may be high bandwidth memory (HBM).

The high bandwidth memory (HBM) is a high-performance three-dimensional (3D) stacked dynamic random-access memory RAM (DRAM). The high bandwidth memory (HBM) is manufactured by stacking memory dies vertically to form a single memory stack. The high bandwidth memory (HBM) may implement shorter latency and higher bandwidth compared to conventional DRAM products by stacking memory dies vertically to have multiple memory channels, while reducing the total area occupied by individual DRAMs on a printed circuit board (PCB), which is advantageous for high bandwidth to area and may reduce power consumption.

The high bandwidth memory (HBM) is designed so that the connection members connecting the memory dies have ultra-fine pitches. According to the present disclosure, the anisotropic conductive film (ACF) 121A on which the conductive particles 122 are locally disposed is used, thereby connecting memory dies of the high bandwidth memory (HBM).

The semiconductor package 20 includes a buffer die 700, the first semiconductor dies 110, the interconnection structure 120, and a molding material 800. The buffer die 700 is disposed at the bottom of the semiconductor package 20. When data is exchanged between devices with different data processing speeds, processing units, and usage times, data loss may occur due to differences in data processing speeds, processing units, and usage times between each device. To prevent such loss, the buffer die 700 is included, and when exchanging data between the first semiconductor dies 110 and an external device, such data is temporarily stored in the buffer die 700 (e.g., in buffers of the buffer die 700). When transmitting data to or receiving data from the first semiconductor dies 110, the buffer die 700 arranges the order of the data and then sequentially passes the data to its appropriate destination.

The first semiconductor dies 110 are disposed on the buffer die 700. The first semiconductor die 110 on which no through substrate vias are formed is disposed at the top of the memory stack. The interconnection structure 120 is disposed between the first semiconductor die 110 and the buffer die 700 and between the first semiconductor dies 110. The first semiconductor die 110 and the buffer die 700, and the neighboring first semiconductor dies 110 are bonded to each other by the anisotropic conductive film (ACF) 121A on which the conductive particles 122 are locally disposed.

The molding material 800 is disposed on the buffer die 700 and covers the first semiconductor dies 110 and the interconnection structures 120. The molding material 800 serves to protect and insulate the first semiconductor dies 110 and the interconnection structures 120. In an embodiment, the molding material 800 may be formed of a thermosetting resin such as epoxy resin. In an embodiment, the molding material 800 may be an epoxy molding compound (EMC).

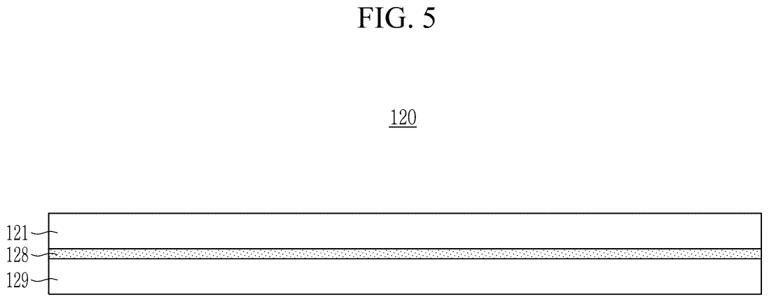

FIGS. 5 to 12 are cross-sectional views illustrating a method of manufacturing the anisotropic conductive film (ACF) 121A according to an embodiment.

FIG. 5 is a cross-sectional view illustrating providing the insulating film 121 to manufacture the anisotropic conductive film (ACF) 121A.

Referring to FIG. 5, the insulating film 121 is attached on a substrate 129. A separation layer 128 is positioned on the substrate 129. The separation layer 128 is a surface-treated layer of the upper surface of the substrate 129. In an embodiment, the substrate 129 may include a slide glass. In an embodiment, the separation layer 128 may be a layer surface-treated with silane.

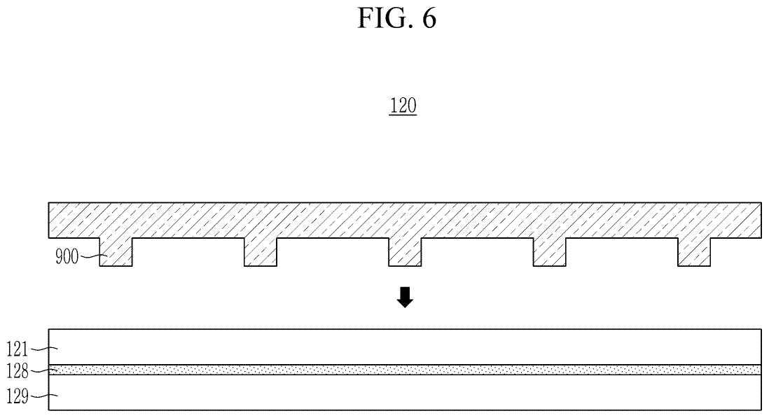

FIG. 6 is a cross-sectional view illustrating aligning a pillar stamp 900 over the insulating film 121.

Referring to FIG. 6, the pillar stamp 900 is positioned over the insulating film 121 attached to the substrate 129. The pillar stamp 900 includes convex portions. In an embodiment, the convex portions may have a circular, oval, polygonal, or conformal shape associated with positions of each of the connection members 127. In an embodiment, the pillar stamp 900 may be a photoresist pattern formed by exposing and developing photoresist and hardening the photoresist by heat treatment. In an embodiment, the pillar stamp 900 may be a polymer pattern obtained by placing and curing a free polymer solution in a mold. In an embodiment, the surface of the pillar stamp 900 on which the convex portions are formed may be surface-treated with silane.

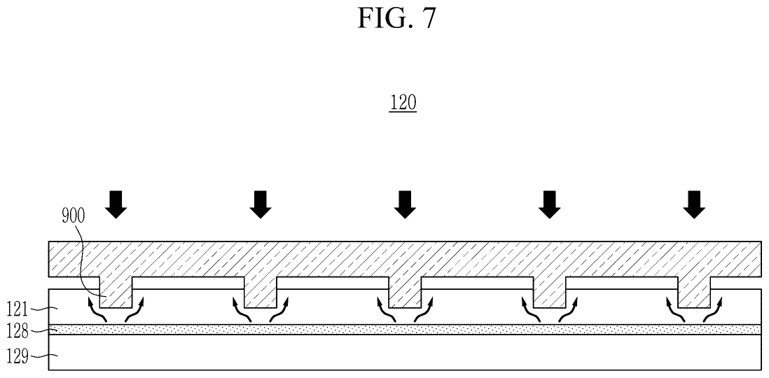

FIG. 7 is a cross-sectional view illustrating forming recess portions in the insulating film 121 using the pillar stamp 900.

Referring to FIG. 7, the insulating film 121 is patterned by the pillar stamp 900. The pattern of the insulating film 121 is formed by contacting the convex portions of the pillar stamp 900 with the insulating film 121 and thermally compressing the insulating film 121 with the pillar stamp 900 (e.g., moving the pillar stamp in the direction of the insulating film 121 to press the insulating film 121 and heating the insulating film with the pillar stamp). The insulating film 121 is patterned and includes recess portions that match the shape of the convex portions of the pillar stamp 900. As recess portions are formed in the insulating film 121, the thickness of the region around the recess portions of the insulating film 121 increases.

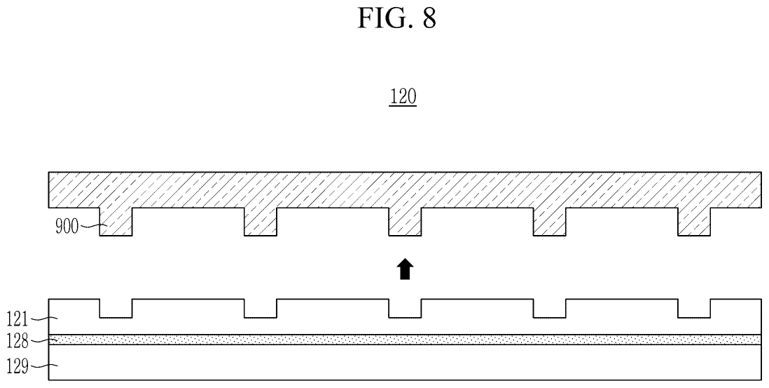

FIG. 8 is a cross-sectional view illustrating removing the pillar stamp 900 from the insulating film 121.

Referring to FIG. 8, the pillar stamp 900 is removed from the insulating film 121. The surface of the pillar stamp 900 on which the convex portions are formed may have been previously surface-treated with silane so that the pillar stamp 900 may be easily removed from the insulating film 121.

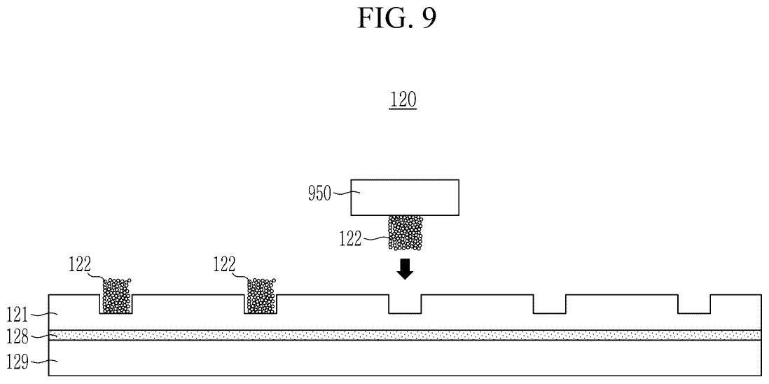

FIG. 9 is a cross-sectional view illustrating disposing the conductive particles 122 in recess portions of the insulating film 121.

Referring to FIG. 9, the conductive particles 122 are attached to an elastic member 950. The elastic member 950 to which the conductive particles 122 are attached moves on the insulating film 121 and sequentially stops on the recess portions of the insulating film 121. The conductive particles 122 move from the elastic member 950 into the recess portions of the insulating film 121. In an embodiment, the elastic member 950 may include polydimethylsiloxane (PDMS).

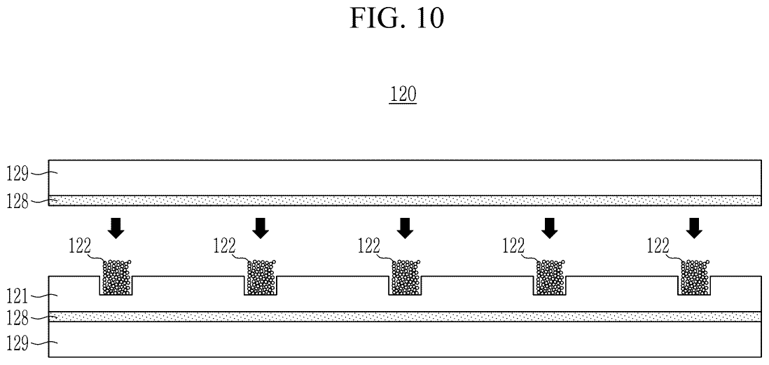

FIG. 10 is a cross-sectional view illustrating aligning the substrate 129 on the insulating film 121 on which the conductive particles 122 are disposed.

Referring to FIG. 10, the substrate 129 is aligned on the insulating film 121 on which the conductive particles 122 are disposed. The separation layer 128 is disposed on the substrate 129. The separation layer 128 is a surface-treated layer of the upper surface of the substrate 129. In an embodiment, the substrate 129 may include a slide glass. In an embodiment, the separation layer 128 may be a layer surface-treated with silane.

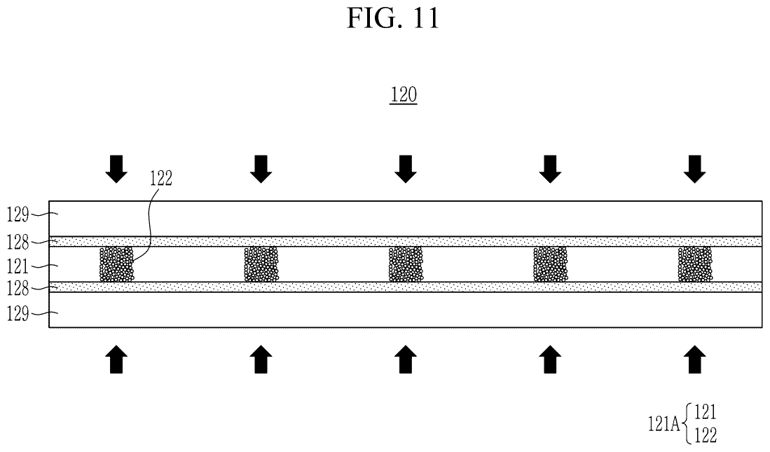

FIG. 11 is a cross-sectional view illustrating compressing the insulating film 121 on which the conductive particles 122 are disposed.

Referring to FIG. 11, the insulating film 121 is thermally compressed using the substrates 129 with the insulating film 121 on which the conductive particles 122 are disposed therebetween. For example, the substrate 129 are used to compress and heat the insulating film. By thermally compressing, the conductive particles 122 are locally inserted into the insulating film 121, and the anisotropic conductive film (ACF) 121A is completed.

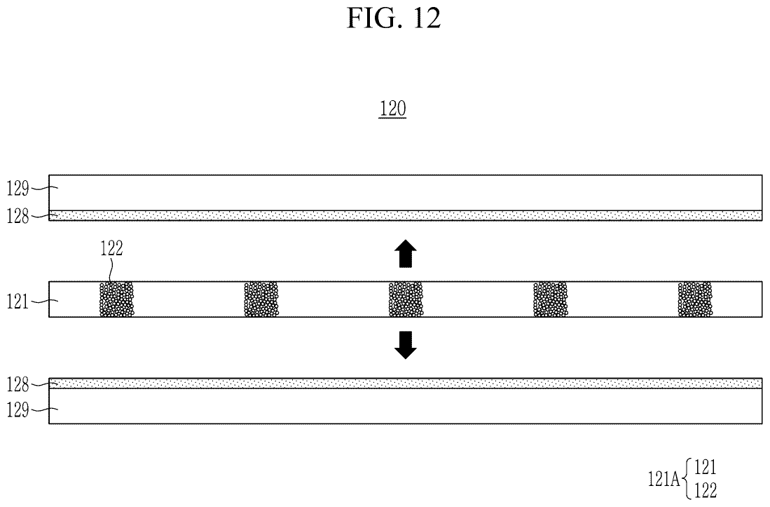

FIG. 12 is a cross-sectional view illustrating removing the substrates 129 from the anisotropic conductive film (ACF) 121A.

Referring to FIG. 12, the substrates 129 attached to the upper portion and lower portion of the anisotropic conductive film (ACF) 121A are removed from the anisotropic conductive film (ACF) 121A. The substrates 129 each include the separation layer 128 so that the substrates 129 may be easily removed from the anisotropic conductive film (ACF) 121A.

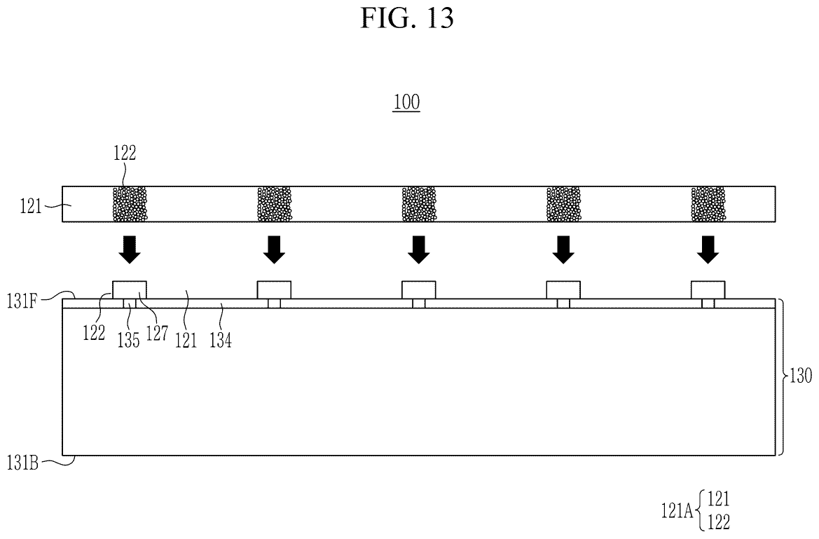

FIGS. 13 to 16 are cross-sectional views illustrating a method of manufacturing the semiconductor stacking structure 100 according to an embodiment of FIG. 1. The method of manufacturing the semiconductor stacking structure 100 may initially comprise the method of manufacturing the anisotropic conductive film (ACF) 121A as described with respect to FIGS. 5 to 12 and need not be repeated here.

FIG. 13 is a cross-sectional view illustrating aligning the anisotropic conductive film (ACF) 121A on the front side 131F of the second semiconductor die 130.

Referring to FIG. 13, the anisotropic conductive film (ACF) 121A is aligned on the front side 131F of the second semiconductor die 130 so that the conductive particles 122 in the insulating film 121 are positioned on each of the connection members 127.

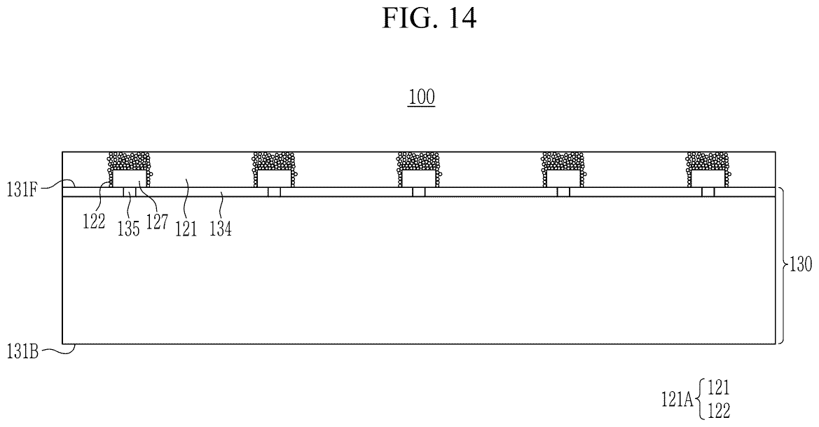

FIG. 14 is a cross-sectional view illustrating attaching the anisotropic conductive film (ACF) 121A on the front side 131F of the second semiconductor die 130.

Referring to FIG. 14, the anisotropic conductive film (ACF) 121A is attached on the front side 131F of the second semiconductor die 130. The connection members 127 are inserted into the insulating film 121. The exposed surfaces of the connection members 127 are surrounded by conductive particles 122.

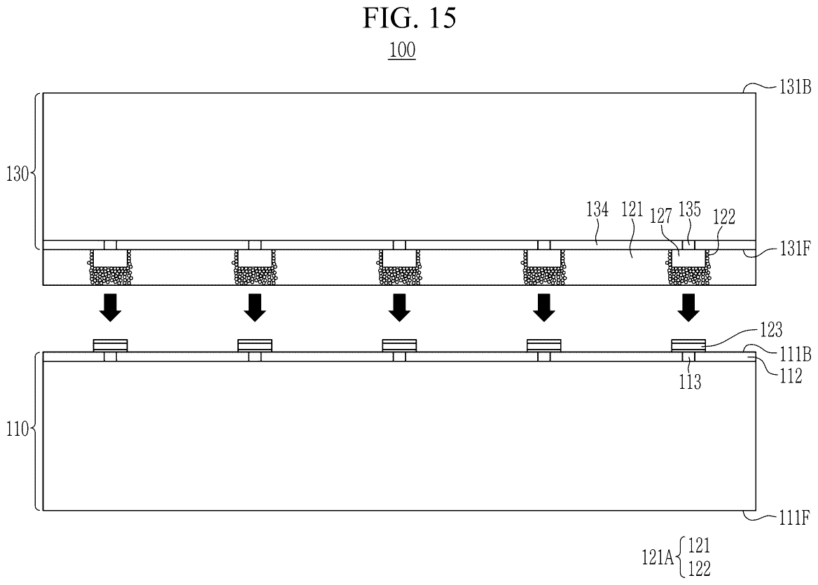

FIG. 15 is a cross-sectional view illustrating aligning the second semiconductor die 130 to which the anisotropic conductive film (ACF) 121A is attached on the back side 111B of the first semiconductor die 110.

Referring to FIG. 15, the second semiconductor die 130 with the anisotropic conductive film (ACF) 121A attached thereto is aligned on the first semiconductor die 110 such that each of the connection members 127 and the conductive particles 122 surrounding each of the connection members 127 are positioned on a corresponding bonding pad of the bonding pads 123.

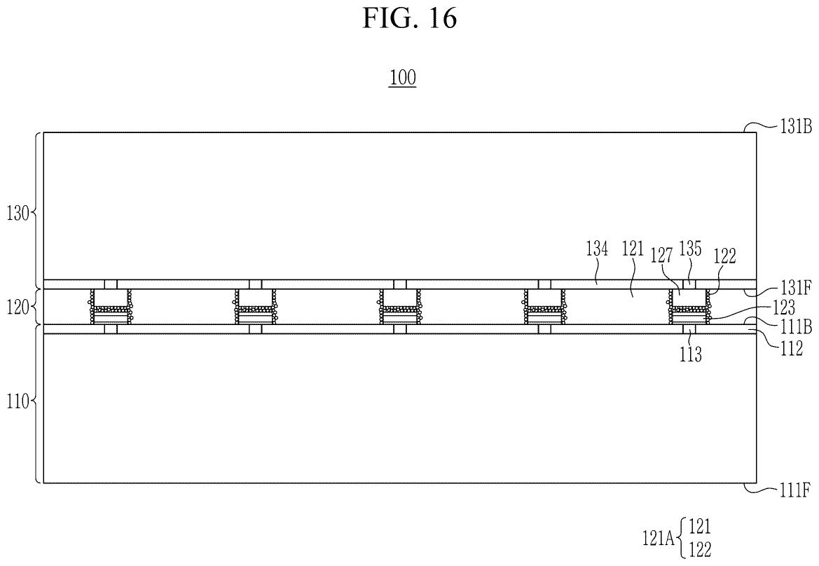

FIG. 16 is a cross-sectional view illustrating the second semiconductor die 130, the anisotropic conductive film (ACF) 121A, and the first semiconductor die 110 attached together, which depicts the semiconductor stacking structure 100.

Referring to FIG. 16, the second semiconductor die 130 is attached to the anisotropic conductive film (ACF) 121A, which is further attached to the first semiconductor die 110. The bonding pads 123 are inserted into the insulating film 121. The surface of each bonding pad among the bonding pads 123 is surrounded by conductive particles 122. Each of the bonding pads 123 is electrically connected to each of the connection members 127 by the conductive particles 122.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the invention.

What is claimed is:

1. A semiconductor package, comprising:
a first semiconductor die;
a plurality of bonding pads on the first semiconductor die;
a plurality of connection members on the plurality of bonding pads, the plurality of connection members being conductive, wherein each connection member of the plurality of connection members is disposed on a corresponding bonding pad of the plurality of bonding pads;
a second semiconductor die on the plurality of connection members; and
an anisotropic conductive film between the first semiconductor die and the second semiconductor die, and between the plurality of bonding pads and the plurality of connection members, the anisotropic conductive film comprising:
an insulating film; and
conductive particles inside the insulating film, wherein the conductive particles are positioned between each of the plurality of connection members and the corresponding bonding pad of the plurality of bonding pads.

2. The semiconductor package of claim 1, wherein
the insulating film comprises a non-conducting film (NCF).

3. The semiconductor package of claim 1, wherein
the insulating film comprises a thermosetting resin.

4. The semiconductor package of claim 1, wherein
the insulating film comprises acryl resin or epoxy resin.

5. The semiconductor package of claim 1, wherein
the conductive particles electrically connect each of the plurality of connection members to a corresponding bonding pad of the plurality of bonding pads.

6. The semiconductor package of claim 1, wherein
each of the conductive particles comprises metal particles coated with a conductive metal layer or polymer particles coated with a conductive metal layer.

7. The semiconductor package of claim 6, wherein
the metal particles comprise nickel, solder, or copper.

8. The semiconductor package of claim 6, wherein
the conductive metal layer comprises at least one of nickel, gold, silver, copper, platinum, palladium, cobalt, tin, indium, and indium tin oxide (ITO).

9. The semiconductor package of claim 1, wherein
the plurality of connection members comprise micro bumps.

10. The semiconductor package of claim 1, wherein
each of the plurality of bonding pads comprises:
a seed metal layer;
a nickel layer on the seed metal layer; and
a gold layer on the nickel layer.

11. The semiconductor package of claim 1, wherein
a horizontal pitch between the connection members is in the range of 4 micrometers to 100 micrometers.

12. A semiconductor package, comprising:
a first semiconductor die;
a second semiconductor die on the first semiconductor die; and
an interconnection structure between the first semiconductor die and the second semiconductor die,
wherein the interconnection structure comprises:
a plurality of bonding pads on the first semiconductor die;
a plurality of connection members under the second semiconductor die, the plurality of connection members being conductive, wherein each connection member of the plurality of connection members is disposed on a corresponding bonding pad of the plurality of bonding pads; and
an anisotropic conductive film surrounding the plurality of bonding pads and the plurality of connection members, wherein
the anisotropic conductive film comprises first regions and a second region other than the first regions,
each first region of the first regions surrounds a corresponding bonding pad of the plurality of bonding pads with respect to a top down view, surrounds a corresponding connection member of the plurality of connection members with respect to the top down view, and is positioned between the corresponding bonding pad of the plurality of bonding pads and the corresponding connection member of the plurality of connection members,
the anisotropic conductive film comprises an insulating film and conductive particles inside the insulating film, and
the conductive particles are positioned in the first regions and not in the second region.

13. The semiconductor package of claim 12, wherein
within each of the first regions, some of the conductive particles contact side surfaces of the corresponding bonding pad among the plurality of bonding pads, and some of the conductive particles contact the side surfaces of the corresponding connection member among the plurality of connection members.

14. The semiconductor package of claim 12, wherein
the first semiconductor die is the same type as the second semiconductor die.

15. The semiconductor package of claim 14, wherein
the first semiconductor die and the second semiconductor die are dynamic random access memory (DRAM).

16. The semiconductor package of claim 12, wherein
the first semiconductor die forms a different type of integrated circuit from that of the second semiconductor die.

17. The semiconductor package of claim 16, wherein
the first semiconductor die comprises a central processing unit (CPU) or a graphic processing unit (GPU).

18. The semiconductor package of claim 16, wherein
the second semiconductor die comprises at least one of a memory, a communication chip, a controller, and a sensor.

19. A method for manufacturing a semiconductor package, comprising:
forming an anisotropic conductive film by inserting conductive particles into each first region of first regions of an insulating film, wherein the insulating film comprises the first regions and a second region other than the first regions;
attaching the anisotropic conductive film on an upper semiconductor die on which a plurality of connection members are disposed, the plurality of connection members being conductive, wherein each first region of the first regions aligns with a corresponding connection member of the plurality of connection members;
aligning the upper semiconductor die on which the plurality of connection members are disposed with a lower semiconductor die on which a plurality of bonding pads are disposed; and
inserting each of the plurality of bonding pads into a corresponding first region of the first regions, and bonding each of the plurality of bonding pads to a corresponding connection member of the plurality of connection members, wherein at least some of the conductive particles are positioned between each of the plurality of bonding pads and the corresponding connection member of the plurality of connection members.

20. The method for manufacturing the semiconductor package of claim 19, wherein
the inserting of conductive particles into each first region of the first regions of the insulating film comprises:
forming a plurality of recess portions in the insulating film by pressing a filler stamp on the insulating film; and
disposing the conductive particles within each of the plurality of recess portions.
